(19) United States
(12) Patent Application Publication
(10) Pub. No.: US 2017/0309708 A1
(43) Pub. Date: Oct. 26, 2017

(54) FIELD EFFECT TRANSISTOR

(71) Applicant: UNITED MICROELECTRONICS CORP., Hsin-Chu City (TW)

(72) Inventors: YI CHUEN ENG, Tainan City (TW); Teng-Chuan Hu, Tainan City (TW); I-Chang Wang, Tainan City (TW); Wei-Chih Chen, Tainan City (TW); Ming-Chih Chen, Hsinchu City (TW)

(21) Appl. No.: 15/169,753

(22) Filed: Jun. 1, 2016

(30) Foreign Application Priority Data
Apr. 21, 2016 (TW) 105112392

(51) Int. Cl. H01L 29/06; H01L 29/10; H01L 29/08; H01L 29/78

(52) U.S. Cl. CPC H01L 29/0692; H01L 29/78; H01L 29/0653; H01L 29/0847; H01L 29/1033

(57) ABSTRACT

A field effect transistor is provided in the present invention with an active area including a source region, a drain region, and a channel region. The width of the channel region is larger than the width of the source/drain regions, and at least one of the source region and the drain region is comb-shaped.

### BACKGROUND OF THE INVENTION

### 1. Field of the Invention

The present invention is related to a field effect transistor, more specifically, to a field effect transistor with special pattern of the active area (AA) including comb-shaped source/drain regions and extending channel region to suppress short channel effect and solve drain induced barrier lowering (DIBL) issue.

### 2. Description of the Prior Art

Metal-Oxide-Semiconductors (MOS) transistors are widely used transistors. A conventional normal transistor includes a gate, a source and a drain. The source and the drain are respectively located in a substrate, and the gate is located on the substrate between the drain and the source to control the switching of currents in a channel below the gate and sandwiched by the source and the drain. Generally, transistors may be classified into planar transistors and non-planar transistors, such as multi-gate MOSFET or fin-type FET.

Generally, when the sizes of semiconductor devices are shrinking, the power consumption can be reduced and the response time can also be shortened relatively. In addition, since the required material is reduced, extra manufacturing cost can also be saved. Therefore, how to shrink the sizes of semiconductor devices has always been an important topic when it comes to the development of semiconductor manufacturing. However, when the sizes of semiconductor devices are too small, for example smaller than 90 nm, the short channel effect becomes more obvious. The drain induced barrier lowering, DIBL, caused by the short channel is one example.

In the transistor suffering short channel effect, not only is the energy level of the channel lowered by the bias voltage V_{d}, but the energy gap between the source and the channel is also lowered due to the short channel effect. The lowered energy gap makes it easier to transmit carriers into the channel in the transistor suffering short channel effect, which also implies that the leakage current is increased and the sub-threshold voltage can be changed with the bias voltage V_{d}. In addition, it becomes harder to turn off the channel of the semiconductor device by the gate voltage when the sub-threshold swing increases.

Since the short channel effect can increase the leakage current and power consumption of the semiconductor devices and the sub-threshold swing can cause the difficulty of controlling the semiconductor devices, how to avoid the inconvenience caused by the short channel effect while shrinking the sizes of the semiconductor devices has become a critical issue to be solved in the semiconductor process.

### SUMMARY OF THE INVENTION

In order to solve the above-mentioned issues of short channel effect, drain induced barrier lowering (DIBL), and sub-threshold swing induced by the downscale of the integrated circuit, a novel pattern of the active area is provided in the present invention to suppress the encroachment of drain electric field in the channel region and solve the above-mentioned issues effectively.

One purpose of the present invention is to provide a novel field effect transistor. The field effect transistor includes a substrate, an active area on the substrate with a source region, a drain region and a channel region, and a gate on the channel region. The width of the channel region is larger than the width of source/drain regions, and at least one of the source region and the drain region is comb-shaped.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Features will become apparent to those of ordinary skill in the art by describing in detail exemplary embodiments with reference to the attached drawings, in which:

FIG. 1A illustrates a schematic top view of the active area of a field effect transistor according to one embodiment of the present invention;

FIG. 1B illustrates a schematic top view of the active area of a field effect transistor according to another embodiment of the present invention;

FIG. 1C illustrates a schematic top view of the active area of a field effect transistor according to still another embodiment of the present invention;

FIG. 2 illustrates a schematic cross-sectional view of the field effect transistor taken along the line A-A′ of FIG. 1A according to one embodiment of the present invention;

FIG. 3 illustrates a schematic cross-sectional view of the field effect transistor taken along the line B-B′ of FIG. 1A according to one embodiment of the present invention;

FIG. 4 illustrates a schematic cross-sectional view of the field effect transistor taken along the line C-C′ of FIG. 1A according to one embodiment of the present invention;

FIG. 5 illustrates a schematic cross-sectional view of the field effect transistor taken along the line D-D′ of FIG. 1A according to one embodiment of the present invention; and

FIG. 6 illustrates a schematic perspective view of the active area of a field effect transistor according to one embodiment of the present invention.

### DETAILED DESCRIPTION

Advantages and features of embodiments may be understood more readily by reference to the following detailed description of preferred embodiments and the accompanying drawings. Embodiments may, however, be embodied in many different forms and should not be construed as being limited to those set forth herein. Rather, these embodiments are provided so that this disclosure will be thorough and complete and will fully convey exemplary implementations of embodiments to those skilled in the art, so embodiments will only be defined by the appended claims. Like reference numerals refer to like elements throughout the specification.

Embodiments are described herein with reference to several illustrations that are schematic illustrations of idealized embodiments (and intermediate structures) of the active areas and the transistor structure in each section of the present invention. As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

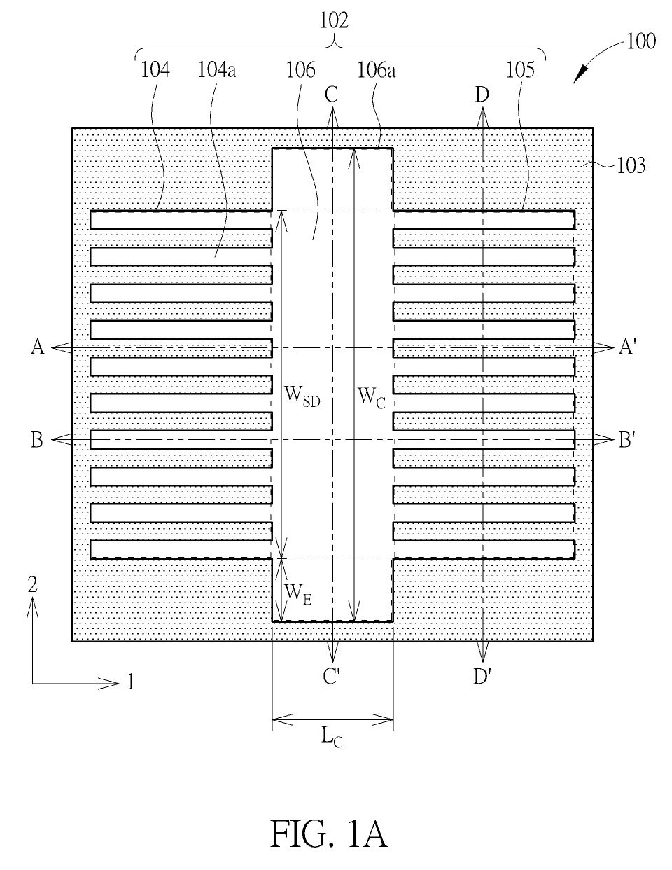

Hereinafter, a field effect transistor according to an embodiment of the present invention will be described with reference to FIGS. 1 to 6. Please note that the present invention is particularly for a planar semiconductor device, and it should not be confused with the 3D semiconductor device, such as FinFET or multi-gate transistor.

Please refer to FIG. 1A, which is a schematic top view of the active area of a field effect transistor according to one embodiment of the present invention. In order to facilitate the description of the embodiment, the gates above the channel regions will be omitted in FIG. 1A. The gate structures will be explicitly described in following other figures. As shown in 1A, the active area 102 in the embodiment includes a source region 104, a drain region 105 and a channel region 106. The source region 104 and the drain region 105 are formed and may extend respectively at both opposite sides of the channel region 106 along a first direction 1. The channel region 106 extends and traverses across the source region 104 and the drain region 105 along a second direction 2. The first direction 1 is preferably perpendicular to the second direction 2. In the present invention, the source region 104 and the drain region 105 are in a comb shape with multiple teeth 104a extending along the first direction 1. Each tooth 104a may serve as a source electrode or a drain electrode. The design of comb-shaped source region 104 and drain region 105 is able to mitigate the short channel effect and achieve a better area utilization ratio in the planar type MOSFET structure. The carrier mobility may also be further increased due to the increase of the strain applied thereon.

In addition to the comb-shaped source/drain regions, another technical feature of the present invention is the extended channel region. As shown in FIG. 1A, both ends of the channel region 106 are respectively provided with extended portions 106a which extend over the source region 104 and the drain region 105 in the second direction 2. In comparison to prior art, the extended portions 106a broaden the width W_{c} of the channel region 106 to an extent wider than the widths W_{SD} of the two adjacent source regions 104 and drain region 105. Wider channel region 106 may improve the performance of the field effect transistor 100, for example, higher saturation current (Iₛₐₜ), less drain induced barrier lowering (DIBL) issue, lower source/drain leakage (Iₗₑₐₖ) , and smaller sub-threshold swing may be achieved. The principle is explained as below:

Q*=Q_{dep} [1−(volₛ+vol_{d})/vol_{g}] (1)

Formula 1 explains relations between the charges within the equivalent depletion region Q* and the other parameters for a field effect transistor. The parameter Q_{dep} represents the charges within the depletion region, the parameter volₛ represents the volume with charges controlled by the source, the parameter vol_{d} represents the volume with charges controlled by the drain, and the parameter vol_{g} represents the volume with charges controlled by the gate in the field effect transistor. When there are more charges within the equivalent depletion regions, the gate can further enhance its control to the channel and the effects caused by the energy gap lowering can also be reduced. According to formula 1, when all the other conditions are not changed, the increase in the vol_{g} can cause the increase in the charges within the equivalent depletion region Q*. Therefore, the present invention adopts the extended portion 106a to enlarge the volume with charges controlled by the gate in the field effect transistor 100, and, thus, to reduce the short channel effect on the field effect transistor. Furthermore, since the field effect transistor has more charges within the equivalent depletion region, the driving current of the field effect transistor 100 can be larger than the driving current of field transistor without extended portion 106a when channels are turned on.

In the embodiment, the width W_{E} of the extended portion 106a is about half of its length L_{c}. This may increase the volume with charges controlled in the active area 102, and may also help to align the gate mask and the extended portions 106a. The active area is preferably in a symmetrical fishbone shape as shown in FIG. 1A, wherein the channel region 106 is solid without any interior heterogeneous portion. The active area 102 is surrounded by an isolation layer 103, such as a shallow trench isolation (STI). The teeth of comb-shaped source/drain region are also isolated by the isolation layer 103. In another embodiment, the channel region 106 may have only one extended portion 106a in one end, and the source region 104 and the drain region 105 is not symmetrical. For example, please refer to FIG. 1B, which is a schematic top view of the active area of a field effect transistor according to another embodiment of the present invention. Only one of the source region 104 and drain region 105 in the structure is comb-shaped. Alternatively, please refer to FIG. 1C, which is a schematic top view of the active area of a field effect transistor according to still another embodiment of the present invention. The teeth pitches of the source region 104 and the drain region 105 are different in this embodiment, depending on the design requirement.

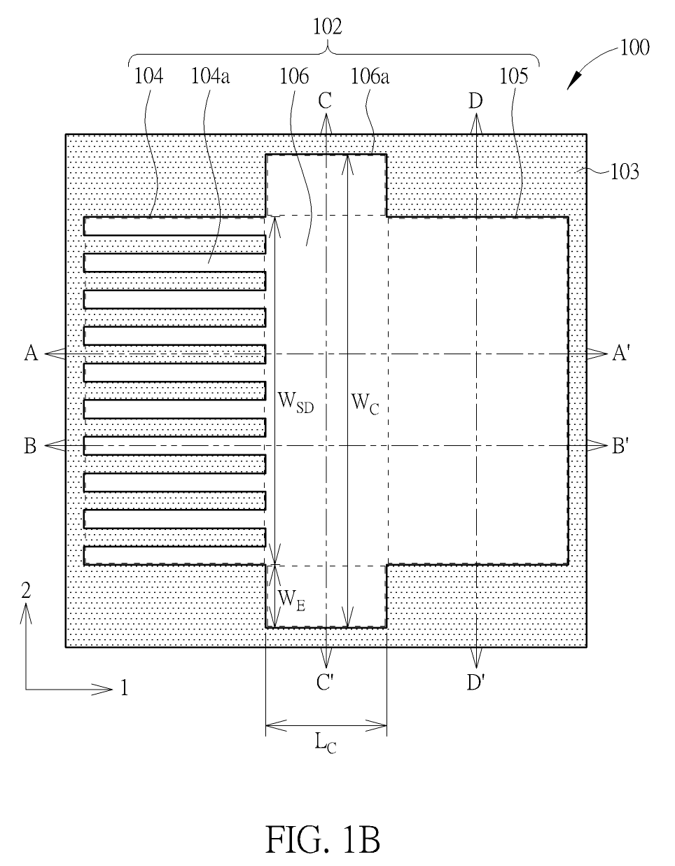

Please refer now to FIG. 2, which is a schematic cross-sectional view of the field effect transistor taken along the line A-A′ of FIG. 1 according to one embodiment of the present invention. The source/drain regions 104/105 are not included in the cross-sectional view. As shown in FIG. 2, the active area 102 is formed on a substrate 101. The substrate 101 may be, for example a semiconductor substrate like silicon substrate, a silicon containing substrate a III/V GaN-on-silicon substrate, a grapheme-on-silicon substrate or a silicon-on-insulator (SOI) substrate. The substrate 101 is defined with various regions for manufacturing different semiconductor devices (i.e. active areas 102), such as a PMOS (P-type metal-oxide semiconductor) region and a NMOS (N-type metal-oxide semiconductor) region defined by the dopant type of well doped in the substrate 100.

In the embodiment, the shape of the active area 102, including channel region 106 and source/drain regions 104/105, may be defined by a photolithographic process and an etch process. For example, forming a patterned photoresist on the well region of the substrate and performing an etch process to etch the region into the shape of active area 102, and the comb-shaped source/drain regions with a width smaller than the critical dimension may be formed by using the sidewall image transfer (SIT) process. The isolation layer 103 is then formed surrounding the active area 102 on the substrate 101, for example, by forming the silicon oxide layer in a CVD process and then removing the excess portions by using a planarization process, so that the silicon oxide layer is flushed with the active area 102 as shown in FIG. 2. A gate electrode 107 (ex. a poly-si gate) is formed on the active area 102 extending along the second direction 2 of FIG. 1A and is parallel and corresponding to the channel region 106. A gate dielectric 108 is formed between the gate 107 and the active area 102.

In the embodiment, the width W_{G} of the gate electrode is smaller than the length L_{c} of the channel region 106. The width W_{G} is preferably half of the length L_{c} of the channel region 106. In ideal condition, the gate electrode 107 is formed right above the center line C-C′ of the active area 102 (FIG. 1A) . However, in real process, the gate electrode 107 may be formed above the position that is slightly shifted to right or left of the center line C-C′ of the active area after the photolithographic process. Nevertheless, the short channel effect maybe suppressed as long as the electric charges in extended portions 106a of the channel region are controlled by the gate 107.

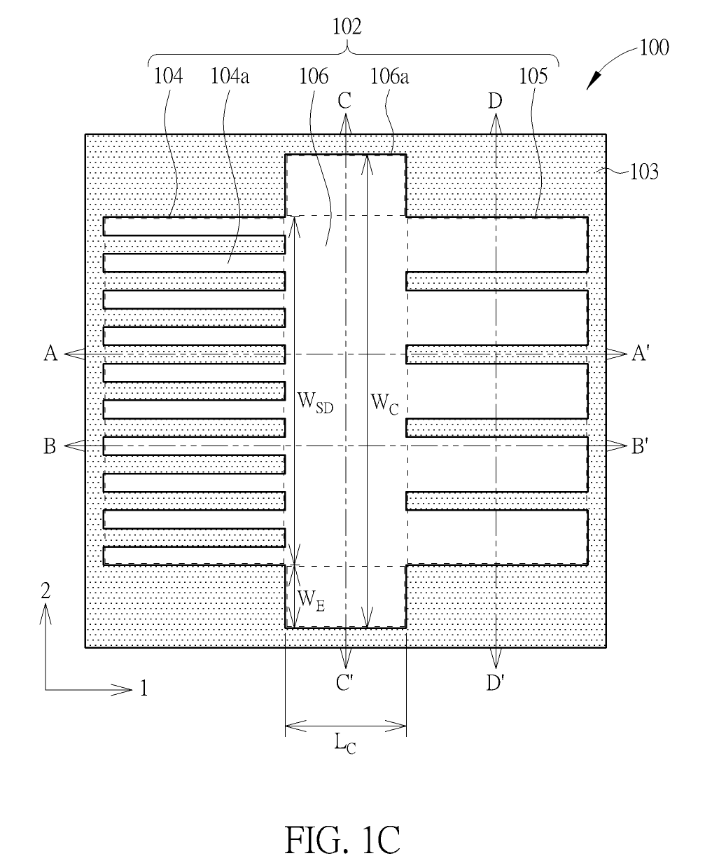

Please refer now to FIG. 3, which is a schematic cross-sectional view of the field effect transistor taken along the line B-B′ of FIG. 1A according to one embodiment of the present invention. This cross-sectional view includes the source/drain regions 104/105 and the channel region 106 in the first direction 1, but the interlayer dielectric and contact structure are omitted in the figure. As shown in FIG. 3, source/drain regions 104/105 are formed respectively at two sides of the channel region 106 and the gate 107. Source/ drain regions 104/105 may be formed by doping the ions with the type different from the one of the preformed well in the substrate. Source/drain regions 104/105 may be formed with light doped drains (LDD, not shown) or source-drain extensions (SDE, not shown) which extend slightly below the gate electrode 107 to mitigate the hot carrier effect. In addition, the etch process and epitaxial growth process may be performed in some embodiment to form strained-Si epitaxial structures as the source/drain on the source/drain regions 104/105 and to increase the carrier mobility.

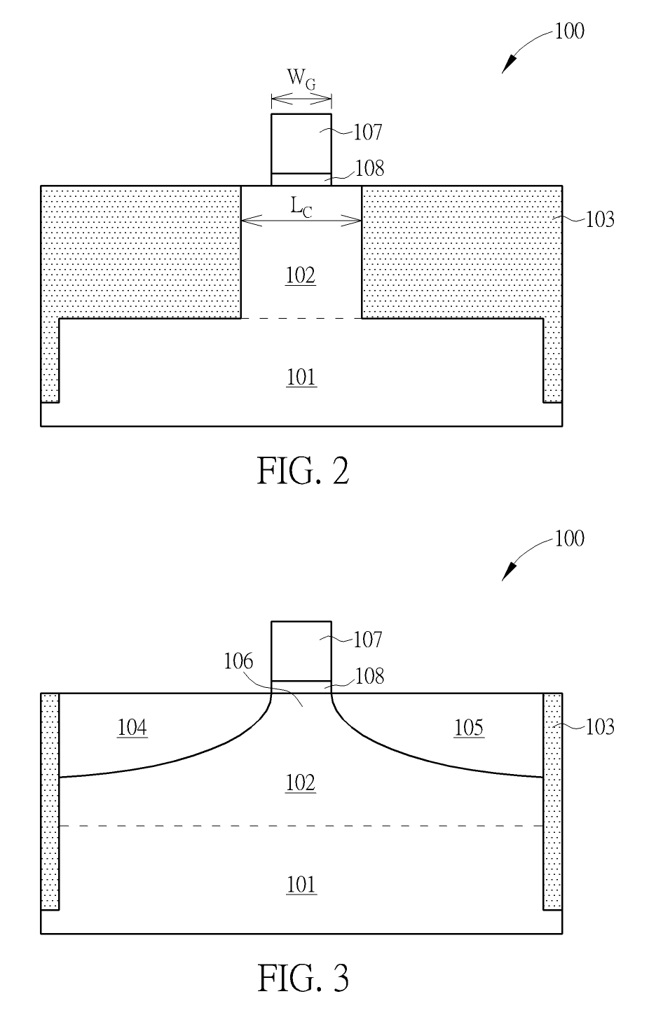

Please refer now to FIG. 4, a schematic cross-sectional view of the field effect transistor taken along the line C-C′ of FIG. 1A according to one embodiment of the present invention. This cross-sectional view includes the whole channel region 106 and gate electrode 107 in the second directions 2 but excludes the source/drain regions 104/105. As shown in FIG. 4, the two ends of the channel region 106 are respectively provided with extended portions 106a which extend over the source/drain regions 104/105 in the second direction 2. Similarly, the gate 107 extends above the two extended portions 106a of the channel region 106. The length of whole gate 107 is approximately equal to the width W_{c} of the channel region 106. In another embodiment, the gate 107 may further extend over the extended portions 106a at two ends in the second direction 2.

Unlike prior art with same widths of the channel region and source/drain regions, the width of the channel region in the present invention is increased by the extended portions of the channel region. Wider channel region may improve the performance of field effect transistors, for example, higher saturation current (Iₛₐₜ) , less drain induced barrier lowering (DIBL) issue, lower source/ drain leakage (Iₗₑₐₖ) and smaller sub-threshold swing may be achieved.

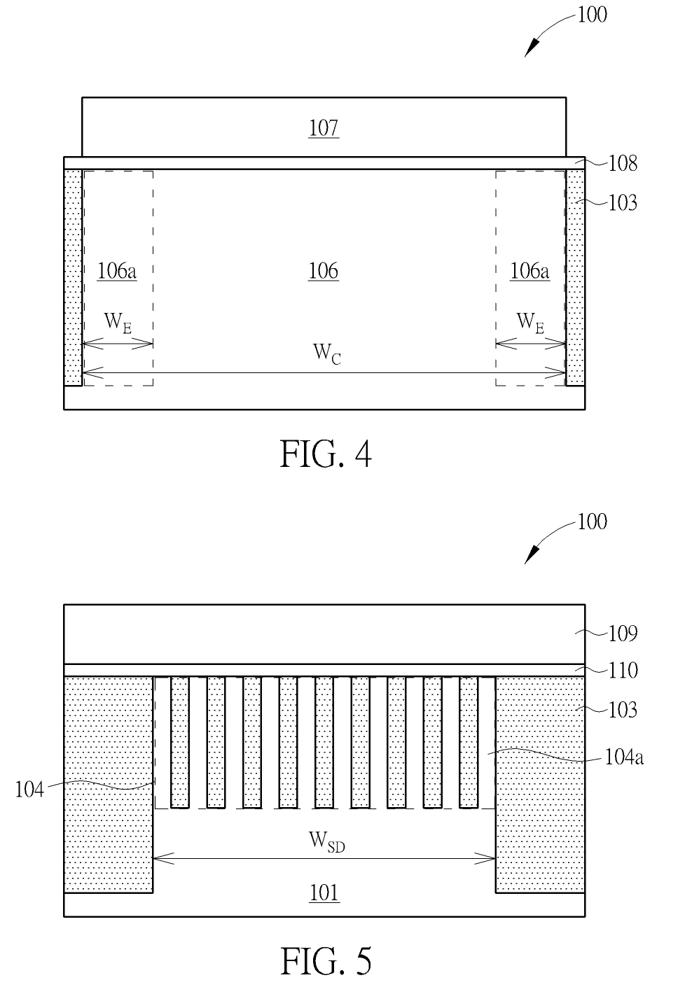

Please refer now to FIG. 5, which is a schematic cross-sectional view of the field effect transistor taken along the line D-D′ of FIG. 1A according to one embodiment of the present invention. The cross-sectional view includes the whole source region 104 (or the drain region 105) in the second direction 2, but excludes the channel region 106 and contact structures. As shown in FIG. 5, the source region 104 is formed on the substrate 101 with a width W_{SD} smaller than the width W_{c} of the channel region 106 having the two extended portions 106a. The source region 104 includes multiple teeth 104a isolated by the isolation layer 103. The design of comb-shaped source region 104 with multiple teeth may help to suppress the short channel effect and achieve a better area utilization ratio in planar type MOSFET structure. The carrier mobility may be further increased due to the increasing strain applied thereon. Similar to the description of FIG. 3, the etch process and epitaxial growth process in some embodiments may be performed to forma strained-Si epitaxial structure as a source electrode on the source region 107 to increase the carrier mobility. Alternatively, a contact etch stop layer 110 (CESL, such as a silicon nitride layer) may be formed on the source region 104 to serve as a stop layer during the contact etch process. The CESL layer 110 may also exert strain on the channel region to increase the carrier mobility. A dielectric layer 109, such as an interlayer dielectric (ILD), is formed on the CESL layer 110, and contact holes and contact structures are formed in the dielectric layer 109 to electrically connect the source region 104 and the drain region 105.

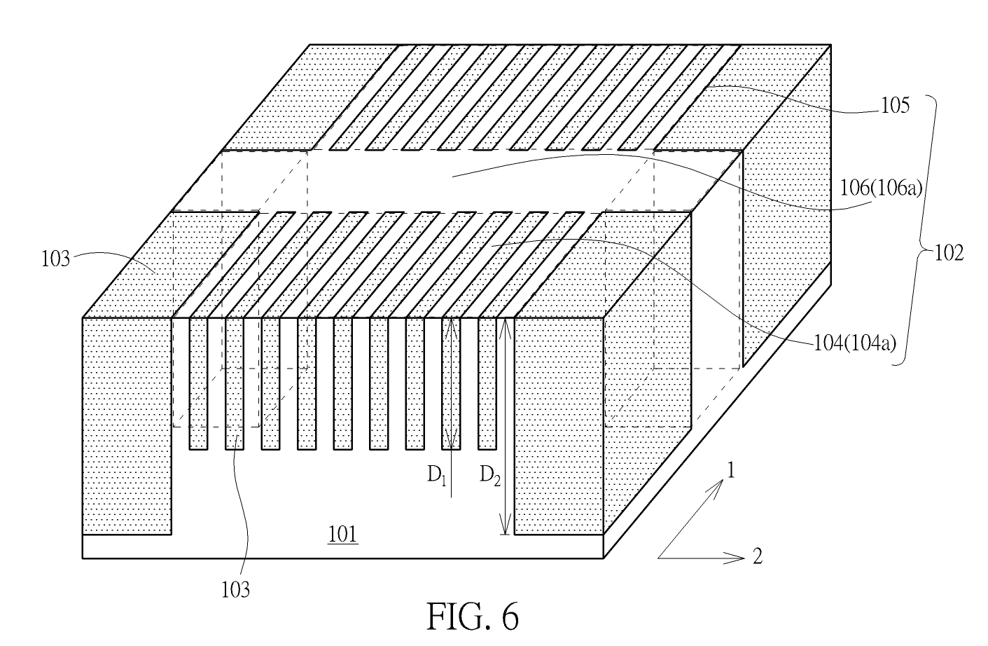

Please refer now to FIG. 6, which is a schematic perspective view of the active area of a field effect transistor according to one embodiment of the present invention. In order to facilitate the description of the embodiment, the gates above the channel regions are omitted in FIG. 6. It is clearly shown in FIG. 6 that the portions of the active area 102, including the channel region 106, source/drain regions 104/105, extended regions 106a, etc., are flushed with the surrounding isolation layer 103. The depth D₁ of the isolation layer 103 between teeth 104a may be the same or different from the depth D₂ of outer isolation layer 103.

Those skilled in the art will readily observe that numerous modifications and alterations of the device and method may be made while retaining the teachings of the invention. Accordingly, the above disclosure should be construed as limited only by the metes and bounds of the appended claims.

1. A field effect transistor comprising:
a substrate;
an active area on said substrate, wherein said active area comprises a source region, a drain region and a channel region, wherein said channel region comprises at least one rectangular extending portion extending over said source region and said drain region in a width direction, and a width of said channel region is larger than a width of said source region, and at least one of said source region and said drain region is comb-shaped, wherein said active area is surrounded by an isolation layer, and teeth of comb-shaped said source region and said drain region are spaced apart by said isolation layer, and a depth of said isolation layer between said teeth of comb-shaped said source region and said drain region is smaller than a depth of said isolation layer surrounding said active area; and
a gate above said channel region.

2. (canceled)

3. The field effect transistor of claim 1, wherein said gate extends over said rectangular extending portion in said width direction.

4. The field effect transistor of claim 1, wherein a length of said gate is equal to half a length of said rectangular extending portion.

5. The field effect transistor of claim 1, wherein a width of said rectangular extending portion is equal to half a length of said rectangular extending portion.

6. The field effect transistor of claim 1, wherein said gate is directly above a center line of said active area, or above a position shifted to right or left of said center line of said active area.

7. The field effect transistor of claim 1, wherein a shape of said active area is a symmetrical fishbone shape.

8-9. (canceled)

10. The field effect transistor of claim 1, wherein both said source region and said drain region are comb-shaped.

11. The field effect transistor of claim 1, wherein said channel region is solid without any interior heterogeneous portion.

12. The field effect transistor of claim 1, wherein only one of said source region and said drain region is comb-shaped.

13. The field effect transistor of claim 1, wherein a pitch of each tooth of said source region and a pitch of each tooth of said drain region are different.
